(19) United States
(12) Patent Application Publication
(10) Pub. No.: US 2025/0384296 A1
(43) Pub. Date: Dec. 18, 2025

(54) SYSTEM OF CREATING A UNIFIED DEEP LEARNING NEURAL NETWORK FOR ANALOG AND MIXED-SIGNAL CIRCUIT CHARACTERIZATION

(71) Applicant: ANALOG INTELLIGENT DESIGN INC., MORGAN HILL, CA (US)

(72) Inventors: DEEPTHI AMURU, Westmead (AU); ZIA ABBAS, Hyderabad (IN); KHANH MINH LE, MORGAN HILL, CA (US)

(21) Appl. No.: 19/241,775

(22) Filed: Jun. 18, 2025

Related U.S. Application Data
(60) Provisional application No. 63/661,535, filed on Jun. 18, 2024.

(51) Int. Cl. G06N 3/0985; G06F 30/38; G06N 3/047

(52) U.S. Cl. CPC G06N 3/0985; G06F 30/38; G06N 3/047

(57) ABSTRACT

The present invention discloses a Unified Deep-Learning Neural Network (U-DNN) Architecture capable of modeling a wide range of AMS circuits effectively and shows the ways it can be used for on demand circuit specification, design optimization and self-adaptation. Applying the U-DNN architecture for analog circuit characterization demonstrated consistent performance across all the DUTs, with an R²Score exceeding 0.95 with {μ_{E},σ_{E}}<1% for the test split data, validating its accuracy. The U-DNN architecture exhibited an average MaPE of less than 1% over unseen test cases, showcasing its strong generalization capabilities. Remarkably, the knowledge encapsulated in the U-DNN architecture, gained from modeling diverse AMS circuits in CMOS 180 nm and 65 nm technologies, translated into accurate modeling of AMS circuits in CMOS 28 nm. The U-DNN architecture serves as a versatile platform for modeling various AMS circuits for different applications, reducing the extensive design exploration time needed to select appropriate NN structures.

### CROSS-REFERENCE TO RELATED APPLICATIONS

This patent application claims priority to pending U.S. provisional patent application No. 63/661,535 filed on 18, June 2024, the complete disclosures of which, in their entirety, are hereby incorporated by reference.

### BACKGROUND

### Technical Field

The embodiments herein generally relate to creating Unified Deep Learning Neural Networks (U-DNN) to characterize circuit performance specifications for analog and mixed-signal (AMS) circuits, and more particularly, to a method and a system for creating a Unified Deep Learning Neural Network (U-DNN) to characterize circuit performance specifications for one or more analog and mixed-signal (AMS) circuits.

### Description of the Related Art

Parameter variability significantly contributes to yield and reliability issues in analog circuit design. These circuits are susceptible to unpredictable and random fluctuations in the manufacturing process and changes in operating temperatures and supply voltage (PVT variations). These PVT variations can lead to significant performance degradation, sometimes rendering the circuit non-operational. There is a direct correlation between the extent of process variations and the production cost due to reduced yield. This variability phenomenon becomes more pronounced as the design progresses to advanced technology nodes. Consequently, the PVT variability analysis emphasizes the importance of considering testability early in the design phase to anticipate potential technical challenges. It also assists in implementing necessary measures in the design, thereby reducing testing costs and minimizing time-to-market delays.

The traditional parameter variability analysis strongly depends on analog designers' intuition, skills, and expertise, with a dearth of formalization constricting the dissemination and reuse of knowledge. Moreover, the difficulty in proposing engineering solutions through conventional methodologies exponentially increases with the circuit complexity, resulting in extended design cycles, time-to-market, and heightened production costs.

Artificial Intelligence and Machine Learning (AI/ML) based variability modeling has become a more viable and promising alternative to address these concerns. These can act as surrogate models, replacing expensive SPICE simulations for circuit characterization.

Neural networks (NNs) have attracted attention as a prominent AI/ML modeling approach across various Analog and Mixed-signal (AMS) applications. They excel in capturing complex circuit behaviors and providing precise models for the inherently high-dimensional, non-linear nature of analog circuit performances. This has led many researchers to investigate NN implementations for tasks such as analog circuit modeling, design sizing, and optimization. The exploration has extended to NN-based transfer learning techniques, which enable reduced data requirements and the utilization of knowledge from pre-existing models. However, the researchers have typically developed distinct NN architectures for modeling the output performances of each specific circuit under examination. This means that circuit-specific NN architectures have been the norm. While there have been instances of applying pre-trained NNs to various topologies of the same circuit, their suitability for entirely new and diverse applications remains uncertain.

FIG. 1 illustrates a conventional neural network design process according to prior art. The traditional method of designing a neural network typically involves stages such as preprocessing, model development, training, and validation. This cycle must be repeated for each analog/mixed-signal (AMS) circuit. While these circuit-specific neural networks can achieve high accuracy for a particular circuit, they require increased design time, resources, and expertise for their development and maintenance. This approach may not always be efficient or practical, especially in scenarios involving multiple circuits or evolving design requirements. The lack of reusability often leads to duplicated efforts in surrogate model development.

When employing the conventional approach of choosing a Deep Neural Network (DNN) architecture for three Dynamic Circuit Models (DCMs) through Bayesian Optimization (BO), as depicted in FIG. 1, the process takes 7,896 seconds. This traditional methodology, which involves designing a suitable neural network for each circuit and each output in every circuit, often necessitates manual efforts and extensive hyperparameter searches using optimization engines. Consequently, it consumes a significant amount of computational time, a cost that increases linearly with the number of circuits and their respective outputs.

Therefore, the existing neural network implementations for analog circuit modeling typically employ circuit-specific architectures. Each circuit requires its own dedicated neural network design, training dataset, and hyperparameter optimization. For example: (i) Circuit-Specific Models: Traditional approaches develop distinct NN architectures for each analog circuit's output performances, requiring separate design space exploration for every new circuit class, (ii) Limited Reusability: While some pre-trained NNs have been applied to topology variations of the same circuit, their applicability to entirely different circuit types remains limited, and (iii) Resource Intensive: Each new analog circuit necessitates a complete neural network development cycle, including preprocessing, model development, training, and validation.

When employing conventional Deep Neural Network (DNN) architecture selection through Bayesian Optimization for multiple circuits, the process requires extensive computational time that scales linearly with the number of circuits and their respective outputs. For three Dynamic Circuit Models (DCMs), traditional methods can require over 7,800 seconds of computation time.

The existing AI/ML-based variability modeling approaches suffer from several deficiencies: (i) Lack of generalization across different circuit topologies, (ii) Inability to leverage learned knowledge from one circuit to accelerate modeling of dissimilar circuits, (iii) Requirement for extensive hyperparameter tuning for each new application, and (iv) Limited scalability when dealing with multiple AMS circuits in a design portfolio. In addition, the training samples are not limited to SPICE simulation results, as they can be measurement results of fabricated analog circuits.

Therefore, there exists a need for a unified neural network architecture that can effectively model diverse AMS circuits while minimizing design time, reducing computational overhead, and enabling knowledge transfer across different circuit applications.

### SUMMARY

In view of the foregoing, an embodiment herein provides a computer-implemented method for creating a Unified Deep Learning Neural Network (U-DNN) to characterize circuit performance specifications for one or more analog and mixed-signal (AMS) circuits. The method includes (i) receiving simulation output data from one or more analog or mixed-signal (AMS) circuits characterized across multiple PVT corners, (ii) extracting electrical performance parameters by preprocessing the simulation output data and converting the data into a normalized feature set, (iii) initializing a deep neural network with one or more hidden layers and neuron configurations, (iv) applying the normalized feature set to the deep neural network having a fixed architecture configured to model PVT-sensitive behavior across diverse AMS circuit topologies without circuit-specific structural modification, (v) applying a Bayesian optimization process to identify optimal hyperparameters, including a neuron count per layer, a learning rate, and a batch size for minimizing prediction error of the deep neural network when trained on the normalized feature set, (vi) training the deep neural network using one or more simulation training samples, as training dataset, for a circuit configuration to generate a unified deep learning neural network (U-DNN) and evaluating the trained unified deep learning neural network model against preset accuracy criteria including a coefficient of determination of at least 95%, (vii) generating by inference one or more circuit specifications, using the trained U-DNN model, and (viii) transmitting the generated circuit specifications to a design tool for optimization, layout, or real-time compensation of the one or more AMS circuits.

In some embodiments, the method includes (i) incrementally increasing the number of hidden layers and retraining the deep neural network if the preset accuracy criteria are not met, (ii) repeating the training process for additional AMS circuits using the same DNN architecture, and increasing the number of training samples per circuit if generalization goals are not met across diverse circuit topologies and (iii) upon satisfying both accuracy and generalization goals, storing the trained deep neural network as the unified U-DNN model for predicting circuit behavior across AMS designs.

In some embodiments, the training dataset includes at least 500 simulation training samples generated using SPICE simulation in Cadence Analog Design Environment, with PVT corner combinations selected to ensure MOSFETs operate within saturation or strong inversion regions. The number of simulation training samples per circuit beyond the at least 500 is dynamically adjusted based on real-time monitoring of prediction accuracy for unseen test samples.

In some embodiments, the U-DNN is trained using simulation datasets including one or more output features of the AMS circuit. The U-DNN is reused without architectural changes across different AMS circuit topologies, with circuit-specific accuracy achieved by additional fine-tuning of weights using circuit-specific training data.

In some embodiments, the PVT corners are selected from one or more process variations, voltage variations, and temperature variations. The neuron counts ranges at least from 32 to 256, learning rates ranges at least from 0.0001 and 0.1, and batch sizes ranges at least from 32 to 64, to minimize validation mean squared error.

In some embodiments, the method includes (i) validating the unified U-DNN model by verifying that it achieves a mean absolute percentage error (MaPE) below 1% or a pre-determined threshold and a standard deviation of prediction error (GE) below 1% or a pre-determined value across the PVT corner combinations, and (ii) determining circuit design parameters from transistor width (W), length (L), bias current (ID), load capacitance, and tail current source resistance, and adjust the circuit design parameters to meet the circuit specifications.

In some embodiments, the method includes (i) determining parameter delta values for components of the one or more AMS circuits and generating corresponding digital control codes to configure programmable analog blocks in real-time, (ii) automatically generating circuit specification reports and parametric plots for performance metrics over user-specified ranges of process, voltage, and temperature on a graphical interface, (iii) triggering automatic recalibration of circuit using parameter output of a secondary model, in response to predicted performance degradation under non-nominal process-voltage-temperature (PVT) conditions, and (iv) performing iterative U-DNN-based characterization and parameter compensation process across successive design revisions to converge on an AMS circuit that satisfies all specification constraints under worst-case PVT scenarios.

In one aspect, a computer-implemented method for characterizing performance specifications of one or more analog or mixed-signal (AMS) circuits using a Unified Deep Learning Neural Network (U-DNN) is provided. The method includes (i) creating an initial design of an analog or mixed-signal (AMS) circuit topology, (ii) executing at least 500 simulation training samples runs across multiple process-voltage-temperature (PVT) corners to generate a training dataset including circuit behavior over variations in device parameters and operating conditions, (iii) extracting electrical performance parameters by preprocessing simulation output data received from one or more analog or mixed-signal (AMS) circuits and converting the data into a normalized feature set, (iv) training a first machine learning model based on a Unified Deep Learning Neural Network (U-DNN) architecture, to characterize the performance specifications of the one or more AMS circuits across the PVT space, (v) generating, in parallel, a second machine learning model configured to model the circuit specifications as a function of key device-level parameters, wherein the second model is selected from a random forest regression, a polynomial regression, or an interpretable regression technique, (vi) applying the second machine learning model to analyze the circuit performance to variations in individual design parameters and to identify influential components and influential factors affecting the circuit specifications, (vii) visualizing the influence of parameter variations using a parametric plot or a heatmap to derive actionable design insights related to the circuit performance over PVT, and (viii) refining the circuit design or control strategy based on insights obtained from both the U-DNN and the secondary model to improve compliance with the circuit specifications under nominal and non-nominal conditions.

In some embodiments, the method further includes (i) re-centering the values of the influential component parameters of the AMS circuits based on insights obtained from the secondary machine learning model, (ii) generating an updated circuit design incorporating the re-centered parameters, (iii) re-executing a set of at least 500 simulations to retrain both the U-DNN model and the secondary model with updated circuit data, and (iv) performing a validation process by exercising a plurality of performance inquiries to verify that the updated circuit design satisfies the circuit specifications across the specified range of PVT corners.

In some embodiments, the method further includes (i) predicting, for each PVT condition, the deviation of one or more performance specifications of the AMS circuits from those obtained under nominal conditions, using the trained U-DNN model, (ii) determining, using the secondary machine learning model, updated values of the influential circuit component parameters required to compensate for the predicted deviations and restoring the specifications to nominal levels, and (iii) generating digital control codes to actuate adaptive elements of the circuit and apply the determined parameter adjustments in real-time.

In another aspect, a system for creating a Unified Deep Learning Neural Network (U-DNN) used to characterize circuit performance specifications for one or more analog and mixed-signal (AMS) circuits is provided. The system includes a memory and a processor. The memory stores a set of instructions. The processor is configured to (i) receive simulation output data from one or more analog or mixed-signal (AMS) circuits characterized across multiple PVT corners, (ii) extract electrical performance parameters by preprocessing the simulation output data and converting the data into a normalized feature set, (iii) initialize a deep neural network with one or more hidden layers and neuron configurations, (iv) apply the normalized feature set to the deep neural network having a fixed architecture configured to model PVT-sensitive behavior across diverse AMS circuit topologies without circuit-specific structural modification, (v) apply a Bayesian optimization process to identify optimal hyperparameters, including a neuron count per layer, a learning rate, and a batch size for minimizing prediction error of the deep neural network when trained on the normalized feature set, (vi) train the deep neural network using one or more simulation training samples, as training dataset, for a circuit configuration to generate a unified deep learning neural network (U-DNN) and evaluating the trained unified deep learning neural network model against preset accuracy criteria including a coefficient of determination of at least 95%, (vii) generate by inference one or more circuit specifications, using the trained U-DNN model, and (viii) transmit the generated circuit specifications to a design tool for optimization, layout, or real-time compensation of the one or more AMS circuits.

In some embodiments, the processor is configured to incrementally increase the number of hidden layers and retraining the deep neural network if the preset accuracy criteria are not met. The processor repeats the training process for additional AMS circuits using the same DNN architecture, and increase the number of training samples per circuit if generalization goals are not met across diverse circuit topologies. The processor stores the trained deep neural network as the unified U-DNN model for predicting circuit behavior across AMS designs upon satisfying both accuracy and generalization goals.

In some embodiments, the training dataset includes at least 500 simulation training samples generated using SPICE simulation in Cadence Analog Design Environment, with PVT corner combinations selected to ensure MOSFETs operate within saturation or strong inversion regions. The number of simulation training samples per circuit beyond the at least 500 is dynamically adjusted based on real-time monitoring of prediction accuracy for unseen test samples.

In some embodiments, the U-DNN is trained using simulation datasets including one or more output features of the AMS circuit. The U-DNN is reused without architectural changes across different AMS circuit topologies, with circuit-specific accuracy achieved by additional fine-tuning of weights using circuit-specific training data.

In some embodiments, the PVT corners are selected from one or more process variations, voltage variations, and temperature variations. The neuron counts ranges at least from 32 to 256, learning rates ranges at least from 0.0001 and 0.1, and batch sizes ranges at least from 32 to 64, to minimize validation mean squared error.

In some embodiments, the processor is configured to (i) validate the unified U-DNN model by verifying that it achieves a mean absolute percentage error (MaPE) below 1% or a pre-determined threshold and a standard deviation of prediction error (GE) below 1% or a pre-determined value across the PVT corner combinations, and (ii) determine circuit design parameters from transistor width (W), length (L), bias current (ID), load capacitance, and tail current source resistance, and adjust the circuit design parameters to meet the circuit specifications.

In some embodiments, the processor is configured to (i) determine parameter delta values for components of the one or more AMS circuits and generating corresponding digital control codes to configure programmable analog blocks in real-time, (ii) automatically generate circuit specification reports and parametric plots for performance metrics over user-specified ranges of process, voltage, and temperature on a graphical interface, (iii) trigger automatic recalibration of circuit using parameter output of a secondary model, in response to predicted performance degradation under non-nominal process-voltage-temperature (PVT) conditions, and (iv) perform iterative U-DNN-based characterization and parameter compensation process across successive design revisions to converge on a AMS circuit that satisfies all specification constraints under worst-case PVT scenarios.

In some embodiments, the trained U-DNN and secondary model are deployed on an edge computing platform co-packaged with an adaptive analog circuit for real-time specification prediction and compensation against changing environmental conditions. In some embodiments, the U-DNN includes at least five hidden layers with neuron counts of 248, 140, 32, 248, and 248 respectively, and uses a rectified linear unit (ReLU) as an activation function.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

The present invention addresses the aforementioned limitations by providing a Unified Deep Learning Neural Network (U-DNN) architecture specifically designed for analog and mixed-signal circuit characterization. The U-DNN features a standardized architecture that can model diverse AMS circuits on different technology nodes and operating across various PVT conditions without requiring circuit-specific architectural modifications.

The advantages of the system includes (i) a single DNN structure applicable to multiple AMS circuit types, (ii) effective characterization starting with only 500 training samples, (iii) validated across 180 nanometer (nm), 65 nm, and 28 nm CMOS processes, (iv) eliminates architectural design time for new circuits and (v) achieves >95% R² score with <1% prediction error. The system further encompasses methods for on-demand specification generation, automated design optimization, and self-adaptive circuit compensation using the trained U-DNN models.

### BRIEF DESCRIPTION OF THE DRAWINGS

The embodiments herein will be better understood from the following detailed description with reference to the drawings, in which:

FIG. 1 illustrates a conventional neural network designing according to prior art;

FIG. 2A illustrates an architecture of a Unified Deep-Learning Neural Network (U-DNN) according to some embodiments herein;

FIG. 2B illustrates a flow diagram of the Unified Deep-Learning Neural Network (U-DNN) development according to some embodiments herein;

FIG. 3 illustrates training results of U-DNN model with different hidden layers with ReLU and ADAM optimizer for DCMs-Mean squared error (MSE) for validation data and R²Score and σ_{E} (% Error in standard deviation) for test data according to some embodiments herein;

FIGS. 4A-4C illustrate trained U-DNN model predictions for the DUTs in comparison with SPICE values according to some embodiments herein;

FIG. 5 illustrates a table view that depicts details of AMS circuits considered for U-DNN design and testing and U-DNN training results after modeling each circuit according to some embodiments herein;

FIGS. 6A-6B illustrate a table view and a graphical illustration that illustrate VCO frequency versus temperature as generated from a machine learning model according to some embodiments herein;

FIG. 7A is the design optimization with U-DNN model according to some embodiments herein;

FIG. 7B is a design optimization with a general machine learning (ML) model according to some embodiments herein;

FIG. 8 is an architecture diagram of the U-DNN-based analog circuit characterization system according to some embodiments herein;

FIGS. 9A & 9B are flow diagrams that illustrate a computer-implemented method for creating a Unified Deep Learning Neural Network (U-DNN) to characterize circuit performance specifications for one or more analog and mixed-signal (AMS) circuits according to some embodiments herein;

FIGS. 10A & 10B are flow diagrams that illustrate a computer-implemented method for characterizing performance specifications of a plurality of analog or mixed-signal (AMS) circuits using a Unified Deep Learning Neural Network (U-DNN) according to some embodiments herein; and

FIG. 11 is a representative hardware environment for practicing the embodiments herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

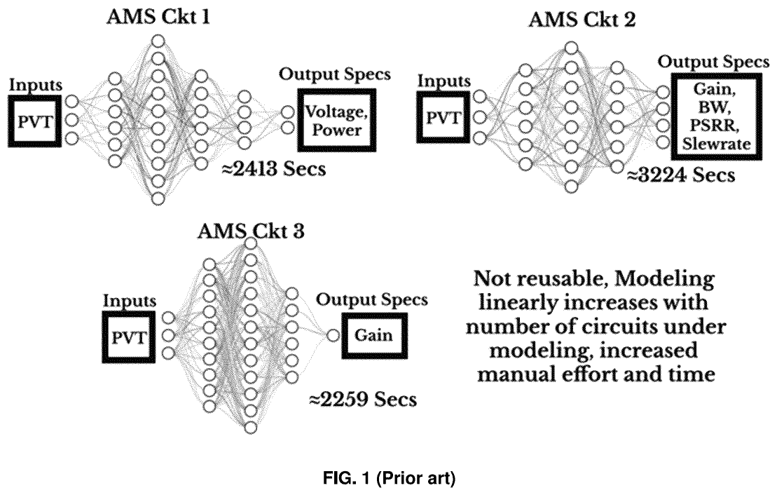

As mentioned, there remains a need for a method and a system for creating a Unified Deep Learning Neural Network (U-DNN) to characterize circuit performance specifications for one or more analog and mixed-signal (AMS) circuits. Referring now to the drawings, and more particularly to FIGS. 1 through 11, where similar reference characters denote corresponding features consistently throughout the figures, preferred embodiments are shown.

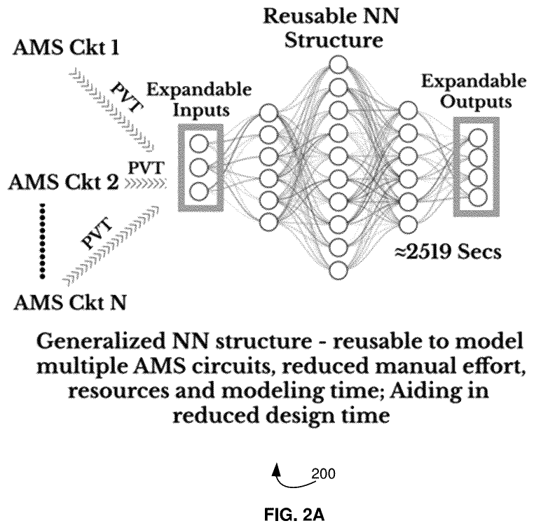

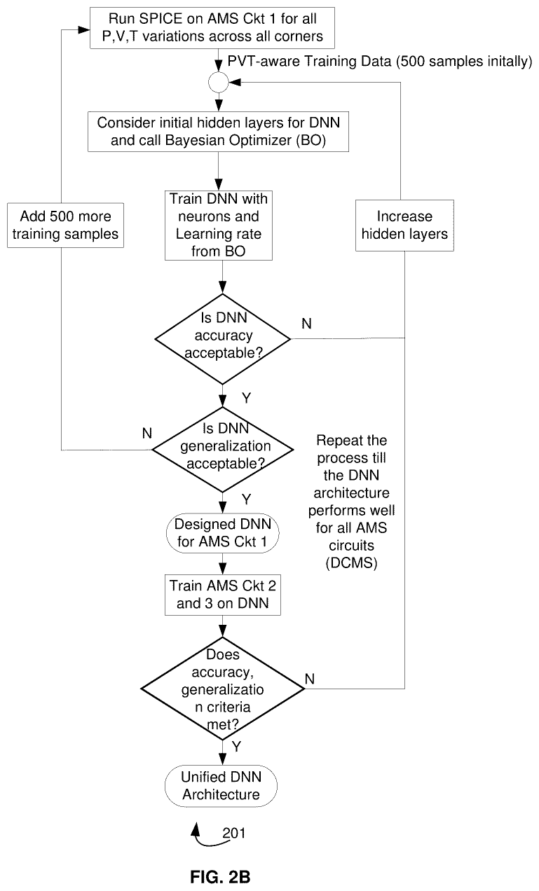

FIG. 2A illustrates an architecture 200 of a Unified Deep-Learning Neural Network (U-DNN) according to some embodiments herein. The Unified Deep-Learning Neural Network (U-DNN) has versatility, reusability, and generality. It is capable of characterizing the PVT-sensitive behavior of a diverse array of analog and mixed-signal (AMS) circuits. The AMS circuits include devices operating in different operating regions under the influence of PVT and span multiple technology nodes. The U-DNN streamlines the process of identifying an appropriate NN architecture, including hidden layers, neuron count, and hyper-parameters, suitable for many AMS circuits, thus saving time and effort. Through careful configuration and evaluation, the U-DNN's performance is assessed by modeling parametric variability across a wide spectrum of AMS designs, encompassing different input and output feature sizes, as well as diverse functionality and interrelationships among them. The designed U-DNN accurately captures performance variations with a modest training dataset (starting with 500 training samples), thereby reducing characterization cost. The U-DNN architecture can be integrated into any simulation-driven NN modeling system, without compromising performance.

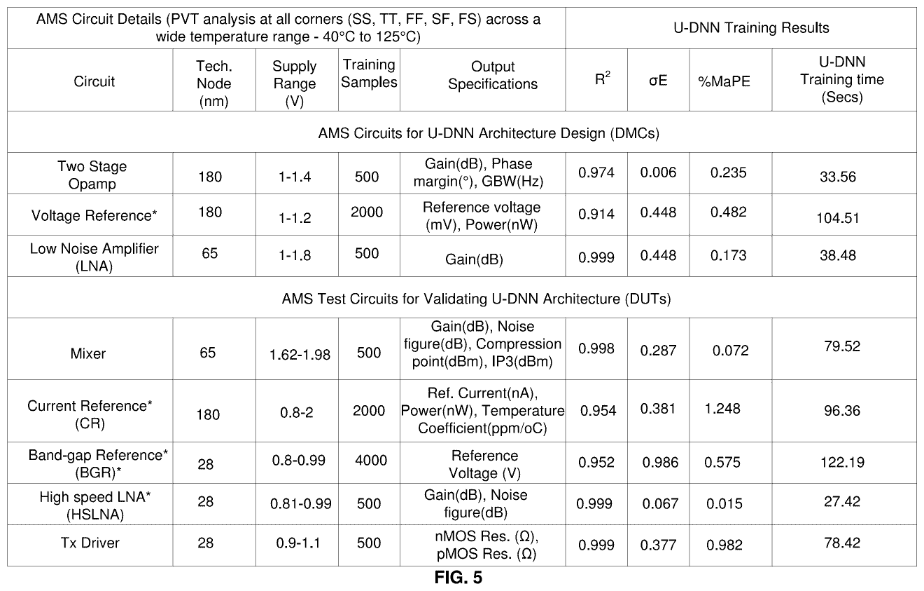

The crucial aspect of creating a dependable surrogate model is producing a PVT-aware statistical behavior across various corners of the AMS circuits. This surrogate model, in return, expedites the generation of solutions within shortened time frames. SPICE simulation results of AMS circuits created within the Cadence Analog Design Environment (ADE) are used to construct training datasets for all the DCMs (Design Circuit under Modeling) and DUTs (Design Under Test) (Table I in FIG. 5). This involved conducting DC, AC, and transient simulations to compute multiple PVT-aware standard performance metrics. The input parameter (PVT) range is selected for each circuit as mentioned in Table I in FIG. 5, ensuring that all MOSFETs function within their desired operational states. Initially, 500 training samples are generated for each circuit, limiting the circuit characterization cost to a minimum. Based on the achieved accuracy of the U-DNN model, more samples are added, if necessary, as shown in the workflow in FIG. 2A.

The U-DNN (Table I in FIG. 5) is designed based on three AMS circuits (DCMs), namely a two-stage Opamp, a voltage regulator, and a low noise amplifier. These circuits operate in different regions and are built with two distinct CMOS technology nodes (180 nanometer (nm) and 65 nm), with different output specifications and unique relationships with PVT. A DNN architecture, including the number of hidden layers, neuron count in each layer, learning rate, suitable optimizer, etc., capable of effectively training these diverse variability-aware circuits is created, resulting in a generalized architecture capable of modeling a wide range of AMS circuits. The aim is to balance precision and generalization while utilizing minimal training data.

FIG. 2B illustrates a flow diagram 201 of the Unified Deep-Learning Neural Network (U-DNN) development according to some embodiments herein. The U-DNN illustrated in FIG. 2B, begins with creating PVT-aware statistical datasets for AMS circuits operating in different corners. Initially, each dataset include only 500 training samples, 90% employed for training (within that 10% allocated for validation) and 10% reserved for testing. In some embodiments, the hyper-parameter search initially began with a DNN structure featuring two hidden layers.

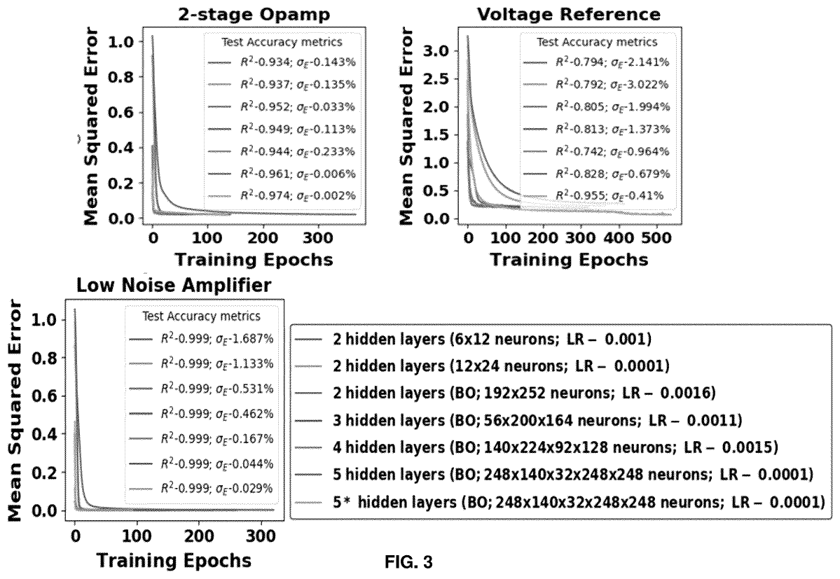

FIG. 3 illustrates training results of U-DNN model with different hidden layers with ReLU and ADAM optimizer for DCMs-Mean squared error (MSE) for validation data and R²Score and σ_{E} (% Error in standard deviation) for test data according to some embodiments herein. To enhance the process, Bayesian Optimization (BO) is employed. BO is an effective multi-objective optimization tool for identifying globally optimal DNN hyperparameters, especially in scenarios characterized by high complexity, non-linearity, and noisy data. This approach allows for more efficient and accurate optimization of the DNN architecture, ensuring robust performance across diverse analog circuit configurations as depicted in FIG. 3.

In some embodiments, TensorFlow and Keras are employed in Python 3.9 to implement the U-DNN. In some embodiments, all the experiments are conducted on an i5 core CPU with 8 GB of RAM. BO is executed for each DCM within a parameter search space ranging from 32 to 256 neurons in each hidden layer. This search encompassed learning rates from 0.0001 to 0.1, employing batch sizes of 32 and 64. Leveraging BO and exploring different combinations of hidden layers and training data size, a DNN architecture with five hidden layers (248×140×32×248×248 neuron count) and a learning rate of 0.0001 is devised. This network takes three inputs (process, voltage, and temperature) and generates diverse (expandable) outputs based on specific circuit requirements. The MSE over validation data during training and performance metrics over the test data for each DCM in the experiments are depicted in FIG. 3.

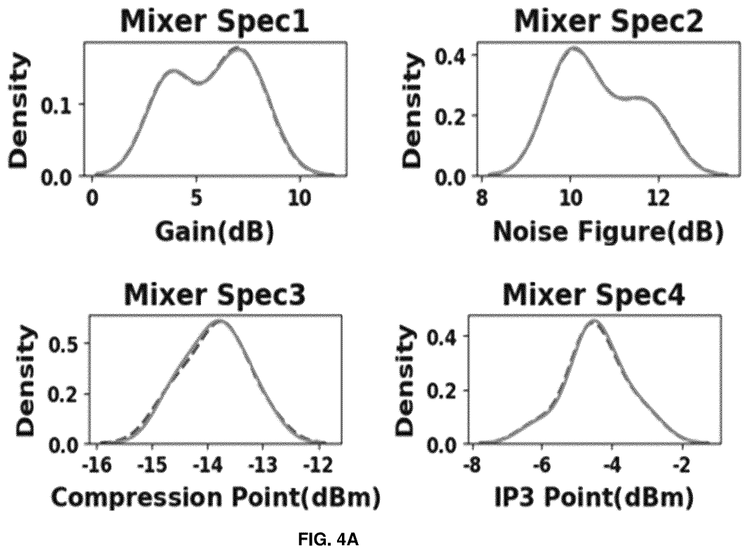

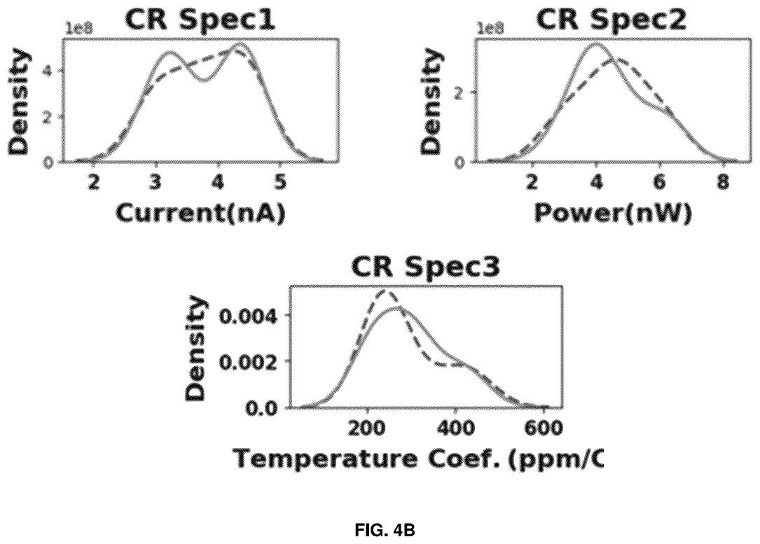

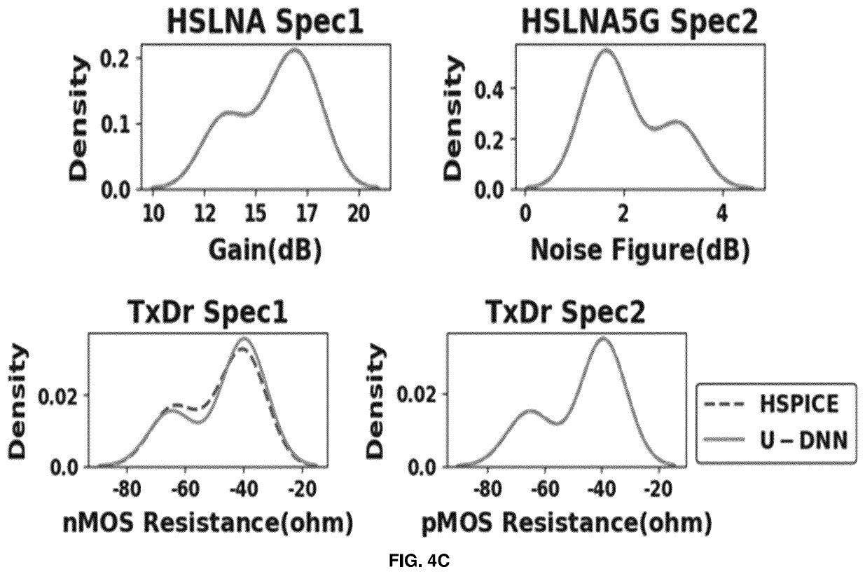

FIGS. 4A-4C illustrate trained U-DNN model predictions for the DUTs in comparison with SPICE values according to some embodiments herein. To evaluate the efficiency of DNN performance, composite training and validation criteria is established, requiring an R²Score>0.95, along with μE and σE both below 1% (the percentage error between the mean and standard deviation of the predicted circuit performances and SPICE values) for all the DCMs. Furthermore, to assess the network's generalization capability, 100 unseen test cases simulated over SPICE in the design space are applied, mirroring the training data distribution to the designed U-DNN and evaluated the mean absolute percentage error, % MaPE, which needed to be less than 1%. In some embodiments, the DNN structure meeting all of the validation criteria are the finalized U-DNN architecture affirming its effectiveness and suitability for the application. These training results are provided in Table I of FIG. 5.

$$MPE = \overline{{{\sum }_{i = 1}}^{N} \vert \frac{SPICE - DNN}{SPICE} \vert} * 100$$

FIG. 5 illustrates a table view that depicts details of AMS circuits considered for U-DNN design and testing and U-DNN training results after modeling each circuit according to some embodiments herein. The U-DNN architecture is developed to achieve adaptability to circuit variations, conserve resources, enhance generalization, and facilitate reusability, as well as streamline model management and integration. These efforts collectively lead to significant time savings in the overall design process. To validate these benefits of the U-DNN, experiments with five distinct test circuits (DUTs) are conducted, detailed in Table I in FIG. 5. Three test circuits from the 0.028 μm technology node, which is not part of the training process, are evaluated and found to be accurately modeled. The U-DNN's effectiveness in accurately modeling these new circuits at the CMOS 0.028 μm node underscores its versatility and robustness. For all the experiments, the U-DNN architecture and associated hyperparameters are kept constant, except for the output layers. For each test circuit, training is performed using the U-DNN structure, with P, V, and T serving as inputs and the respective circuit specifications as outputs. The U-DNN's prediction results (for 20 unseen test cases after verifying the training and testing accuracies as per the set test criteria) for each circuit's output(s) are compared against SPICE simulations and plotted in FIGS. 4A-4C. The ML metrics are provided in Table I (FIG. 5). Notably, all the DUTs report highly accurate training and validation performance, with a MaPE of less than ≤1%. Nonetheless, the current reference circuit reports the most significant discrepancy, reaching 3% in the prediction of the temperature coefficient. On average, across all of its output specifications, the MaPE results in 1.2%. In such instances, U-DNN architecture serves as an advantageous starting point for making adjustments, facilitating a more rapid convergence in the optimization process.

The U-DNN architecture crafted through an in-depth exploration of circuit behavior in response to PVT variations across three distinct DCMs, possesses the versatility to train a broad spectrum of AMS circuits effectively. This capability translates into substantial savings in computational time and resources. The U-DNN architecture represents a one-time design endeavor that can be applied across diverse applications to model numerous AMS circuits, thereby streamlining the modeling process and reducing computational overhead.

Additionally, the SPICE characterization cost is reduced. In each instance, a single SPICE simulation takes roughly 3 seconds. Therefore, generating a set of 500 samples entails a time investment of 1500 seconds. In traditional analog circuit characterization, this cost escalates proportionally with the augmentation of Monte Carlo simulations to meet design specifications. In contrast, leveraging the U-DNN approach requires approximately 2500 seconds for the DNN architecture modeling (a one-time effort) and an average training time of 75-100 seconds for each circuit (Table I in FIG. 5). Predictions for test inputs can be obtained in <5-10 seconds. This exemplifies the advantages of employing AI/ML surrogate modeling, offering substantial time savings in a multitude of scenarios.

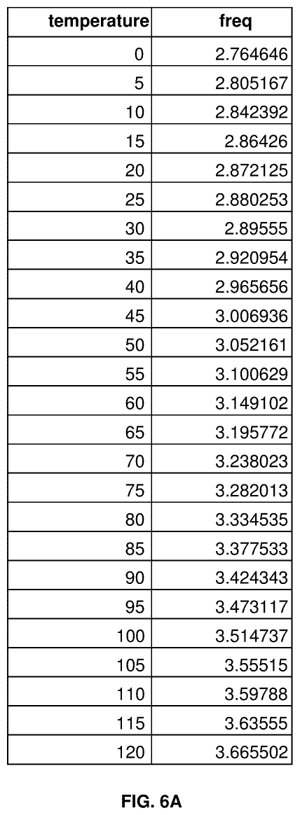

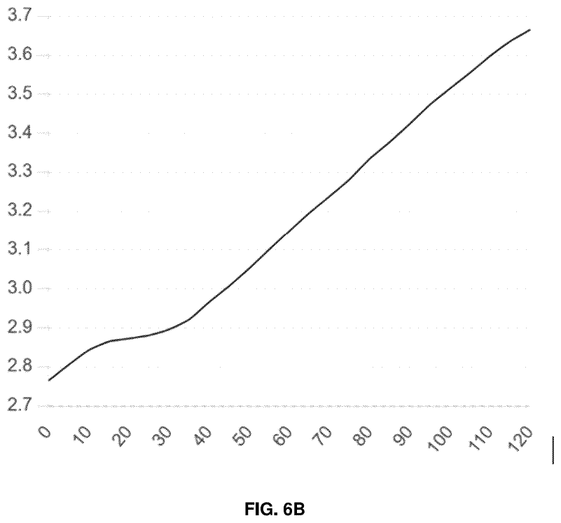

FIGS. 6A-6B illustrate a table view and a graphical illustration that illustrate VCO frequency versus temperature as generated from a machine learning model according to some embodiments herein. The U-DNN architecture is beneficial for companies with a large number of analog circuits to characterize so that their resulting ML models can be applied for on-demand circuit specification, saving time and resources. Once determined to have accurately characterized (or represented) the analog circuit, the U-DNN is used to perform various on-demand generation of circuit specifications for various PVT conditions, both with individual scripts and automated routines. In some embodiments, results are obtained instantaneously as Spice simulations are no longer needed.

The CUT demonstrated in this case is a two-stage operational amplifier. The dataset contains the following columns: (i) process, voltage, and temperature as input features, (ii) Gain, UGB, Phase Margin, Slew rate, PSRR, power as the outputs. Where gain, UGB, Phase Margin, slew rate, PSRR and power are the specifications of the op-amp under design.

In some embodiments, the U-DNN-based model of the circuit is trained from the 500 samples of simulation results for gain, UGB, Phase Margin, slew rate, PSRR and power where the values of P, V, and T are swept as required.

In some embodiments, typical on-demand circuit specification steps are described below.

The values of Gain and PSRR are calculated when all the inputs are at their nominal values (P=TT, V=0.9V, T=27C).

Result: For input values set at their nominal values, the predicted values are: Gain: 82.0084 and PSRR: −99.2323 dB.

The values of all the outputs are calculated when T=32C and all the other inputs are at their nominal values.

Result: With T set to 32C and all other inputs at their nominal values, the predicted values for the outputs are as follows: Gain: 83.5602, UGB: 154.01, Phase Margin: 67.1252 deg, Slew rate: 212.01 V/usec, PSRR: −91.7494 dB and Power: 1.46 uW.

In some embodiments, these values inferred from the U-DNN-based model are verified to be within 1% of the simulation results, showing the high accuracy and versatility of the U-DNN-based model.

The on-demand specification is further possible with automated routines that can be written to create accurate new data from the U-DNN-based model. The next CUT is a 4 GHz VCO on TSMC 28 nm process. The dataset contains the following columns: (i) Process, voltage, temperature, and Vctrl (VCO control voltage) as inputs, and (ii) VCO frequency, VCO gain, and VCO bias (bias voltage at the supply pin of the VCO).

In some embodiments, the U-DNN-based model is created with a Mean Squared Error (MSE) of 0.0163 and an R² Score of 0.997. The high R² score indicates that the model explains a significant portion of the variance in the output variables, and the low MSE suggests that the model's predictions are quite accurate. Using the U-DNN-based model, for v_{dd}=0.85, v_{ctr}l=0.53, the values of the VCO frequency are calculated for temperatures from 0 to 120 in steps of 5 and display the results in a spreadsheet and a plot. Result: The new table and plot have been created and saved successfully.

In some embodiments, several on-demand specification routines similar to the above with the circuits shown in Table I in FIG. 5 and their ML models are performed based on the same U-DNN.

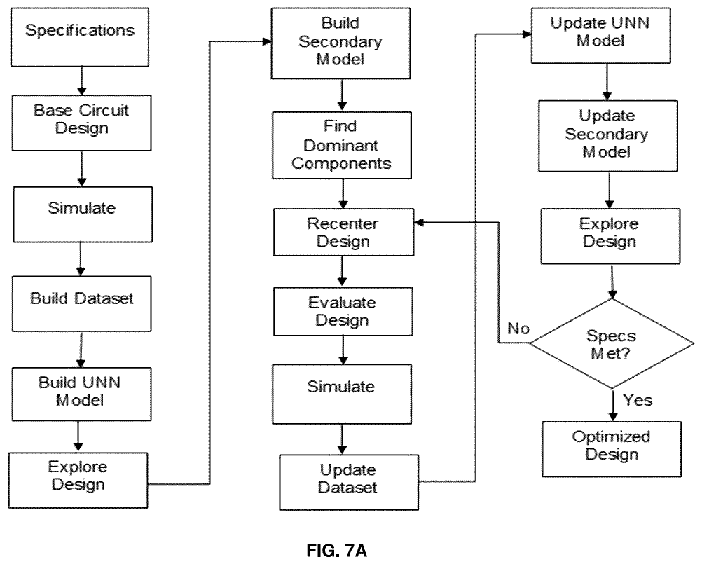

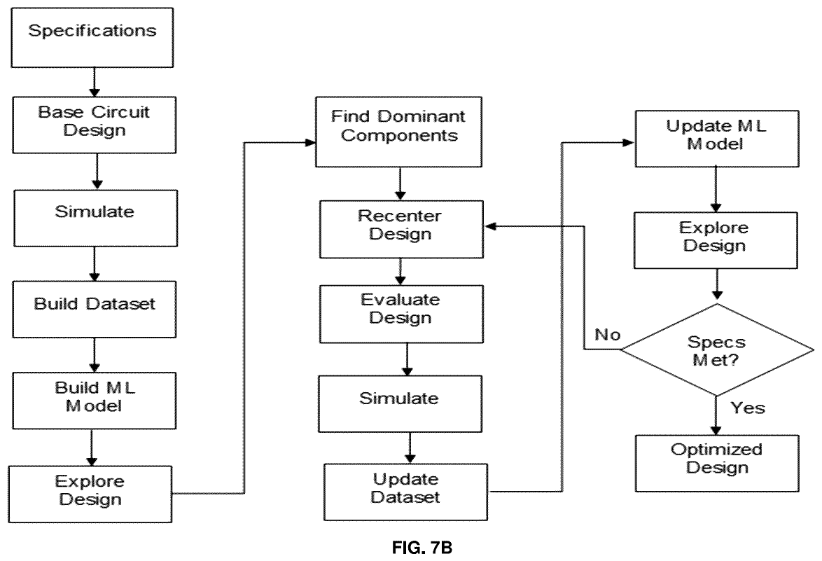

FIG. 7A is a design optimization with U-DNN model according to some embodiments herein. Given its rapid creation and high accuracy, the U-DNN model is highly useful for design optimization. Starting with a preliminary circuit design, 500 simulations are conducted to build the U-DNN model. From the U-DNN model, various inquiries are exercised to quickly gain significant insight into the performance, the variations of the specifications over PVT, and the limitations of the preliminary design.

Further, from the same set of simulation results, a secondary machine learning (ML) model is built to characterize the specifications in relation to the most relevant device parameters such MOS widths and lengths, resistor and capacitor values, etc. In some embodiments, the secondary machine learning model can be created from random forest regression, polynomial regression, etc. The dominant components and their parameters are determined by exercising various inquiries. Further, inquiries into changing the dominant component parameters provided significant insights into performance, variations of specifications over PVT and different device parameter values, and the limits of those parameters. These insights are obtained without requiring any additional simulation runs, with answers provided in real-time.

Using this model for the folded cascode opamp, the Pearson correlation coefficients between “gain” and ID are calculated, then with wn2, then with wn1, then with wd, then with wp2, then with wx, then with wp1, then with cl. ID is the bias current to the opamp, wd, wx, wn and wp are the widths of the MOS devices in the circuit, and cl is the capacitive load value.

Result: Here are the Pearson correlation coefficients between the predicted “gain” and each of the specified input features, including ID:

“Gain” and ID: −0.543, indicating a moderate negative correlation.

“Gain” and wn2: 0.523, indicating a moderate positive correlation.

“Gain” and wn1: 0.650, indicating a strong positive correlation.

“Gain” and wd: 0.198, indicating a weak positive correlation.

“Gain” and wp2: 0.009, indicating virtually no correlation.

“Gain” and wx: −0.006, indicating virtually no correlation.

“Gain” and wp1: 0.037, indicating a very weak positive correlation.

“Gain” and cl: −0.032-0.032, indicating a very weak negative correlation.

These results highlight that “Gain” has a strong positive correlation with wn1, suggesting that as wn1 increases, “Gain” also tends to increase significantly. The moderate negative correlation with ID suggests that as ID increases, “Gain” tends to decrease. The correlations with other features like wn2 and wd also show some influence, albeit less significant than with wn1. Therefore, ID, wn1 and wn2 are the dominant components for “Gain”.

From the insight, the values of the dominant component parameters are re-centered, and an updated circuit design is created. Further, 500 simulations are conducted that are required to update the U-DNN model and the secondary machine learning model. By exercising various inquiries, the specifications over PVT together with a deep knowledge about any limitations of the new design are verified.

The design optimization process using the U-DNN model, and the secondary ML model rapidly converged toward an optimized circuit that not only met all the specifications. The by-product of this process is a set of two very accurate and compact ML models of the optimized circuit that can easily be stored and re-used without further simulations.

FIG. 7B is a design optimization with a general machine learning (ML) model according to some embodiments herein. The design optimization with the general ML model is applied in general to any machine learning model created to characterize the circuit specifications according to PVT and the characteristics of its internal components, as depicted in FIG. 7B and in U.S. non-provisional patent application Ser. No. 17/088,475 filed on Nov. 3, 2020, and U.S. provisional patent application No. 63/605,388 filed on Dec. 1, 2023.

With the optimized circuit design, self-adaptation is performed using the secondary model that characterized the specifications according to the various device parameters. For each worst-case PVT condition, the model is used to calculate the values of the dominant component parameters necessary to bring the specifications back to those at the nominal.

Unified Deep Learning Neural Network (U-DNN) Architecture/Model: The core innovation lies in a standardized deep neural network architecture that maintains consistent structural parameters across diverse analog and mixed-signal circuits. Unlike prior art that requires circuit-specific architectural design, the U-DNN employs a fixed architecture with five hidden layers having neuron counts of 248×140×32×248×248, optimized through comprehensive Bayesian optimization across multiple circuit types.

Universal Input-Output Framework: The U-DNN accepts three standardized inputs (Process, Voltage, Temperature) and generates variable outputs corresponding to circuit-specific performance metrics. This standardization enables knowledge transfer between different circuit applications while maintaining high accuracy for individual circuit characterization.

### Training Dataset Generation and Preprocessing:

PVT-Aware Statistical Datasets: Training datasets are generated using SPICE simulations within the Cadence Analog Design Environment (ADE). The process involves conducting DC, AC, and transient simulations across PVT corners to compute multiple performance metrics. The input parameter ranges are carefully selected to ensure all MOSFETs operate within their intended operational regions.

Minimal Sample Requirement: Initial training commences with only 500 samples per circuit, significantly reducing characterization costs compared to traditional Monte Carlo approaches. Additional samples are incorporated adaptively based on achieved accuracy metrics, enabling cost-effective model development.

### Bayesian Optimization for Architecture Selection:

Hyperparameter Optimization Process: The U-DNN architecture is determined through systematic Bayesian Optimization exploring parameter spaces including: neuron counts: 32 to 256 per hidden layer, learning rates: 0.0001 to 0.1, batch sizes: 32 and 64 and hidden layer configurations: 2 to 6 layers.

Performance Validation Criteria: The final U-DNN architecture selection requires meeting stringent performance criteria: R² Score>0.95 for all Design Circuits under Modeling (DCMs), mean percentage error (μE)<1%, standard deviation percentage error (σE)<1%, and mean Absolute Percentage Error (MaPE)<1% for unseen test cases

Cross-Technology Node Validation: The U-DNN's universality is demonstrated across three CMOS technology nodes (180 nm, 65 nm, 28 nm) using five distinct test circuits (Design Under Test-DUTs). The U-DNN architecture maintains consistent performance across all technology nodes without requiring structural modifications.

Circuit Diversity Coverage: Validation circuits include two-stage operational amplifiers, voltage regulators, low noise amplifiers, voltage-controlled oscillators (VCOs) and current references. Each circuit operates in different regions with unique PVT relationships and output specifications.

On-Demand Specification Generation: Real-Time Performance Prediction: Once trained, the U-DNN enables instantaneous circuit specification generation for arbitrary PVT conditions without additional SPICE simulations. This capability supports interactive design exploration, automated specification sweeps, temperature coefficient analysis and supply sensitivity characterization.

Automated Specification Scripts: The system supports automated routines for generating comprehensive specification tables and plots across user-defined PVT ranges, facilitating rapid design verification and documentation.

Design Optimization Methodology: Dual-Model Optimization Framework: The design optimization process employs two complementary machine learning models: Primary U-DNN Model: Characterizes circuit specifications relative to PVT variations and Secondary Component Model: Relates specifications to internal device parameters using regression techniques (random forest, polynomial regression).

Correlation Analysis and Parameter Identification: The secondary machine learning model enables identification of dominant design parameters through correlation analysis. For example, in operational amplifier optimization, parameters such as bias current (ID) and device widths (wn1, wn2) are identified as primary gain influencers through Pearson correlation coefficients.

Iterative Design Refinement: The optimization process iteratively analyzes current design limitations through model interrogation, identifies dominant parameters affecting key specifications, re-centers parameter values based on optimization insights, updates models with additional simulation data and validates improved design performance.

Self-Adaptive Circuit Compensation: Real-Time Adaptation Capability: The trained models enable self-adaptive circuits that compensate for PVT variations in real-time. For each encountered PVT condition, the system predicts specification changes relative to nominal conditions, calculates required adjustments to dominant component parameters and generates control codes for adaptive circuit elements.

Compensation Algorithm: The adaptation process uses the secondary ML model to determine parameter modifications needed to restore nominal performance:

$$For PVT\_condition \neq nominal : Δ Specs = Primary\_Model ( PVT\_condition ) - Primary\_Model ( PVT\_nominal ) Δ Parameters = {Secondary\_Mode1}^{- 1} ( Δ Specs ) Control\_Codes = Generate\_Adaptation \_Control ( Δ Parameters )$$

In some embodiments, the U-DNN is implemented using TensorFlow and Keras frameworks in Python 3.9 environment. The system operates efficiently on modest hardware configurations (i5 CPU, 8 GB RAM), making it accessible for widespread deployment. The computational efficiency demonstrates significant advantages: The traditional approach: ˜ 7,896 seconds for three circuits, U-DNN approach: ˜ 2,500 seconds for architecture development (one-time)+75-100 seconds per circuit training and prediction time: <5-10 seconds for test inputs. Storage and Deployment: Trained models require minimal storage and can be deployed across different platforms, enabling integration into automated design flows and real-time adaptive systems.

Unlike circuit-specific neural networks, the U-DNN employs a single architecture across diverse AMS applications. The U-DNN achieves high accuracy with only 500 initial samples versus thousands required by traditional approaches. The U-DNN maintains performance across multiple CMOS technology nodes. The U-DNN combines PVT modeling with component-level optimization in a unified system. The U-DNN enables real-time circuit compensation without additional simulations.

Technical Benefits includes: Time Reduction: >90% reduction in neural network development time for new circuits. Minimal simulation requirements reduce characterization costs. The system preserves >95% R² performance across diverse applications. The system provides linear scaling with circuit portfolio size. The system leverages learned representations across different circuit domains.

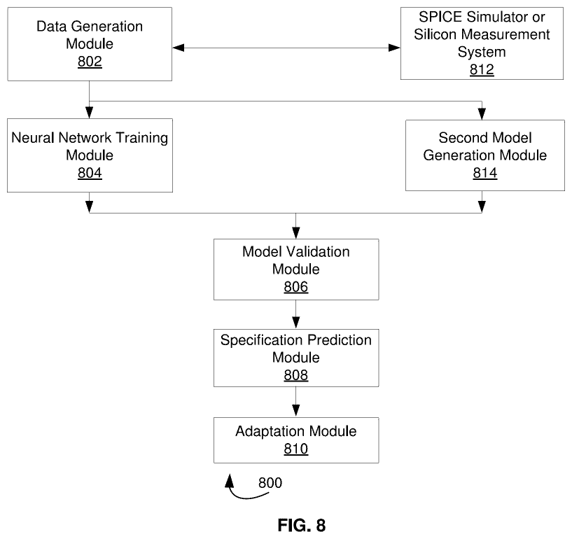

FIG. 8 is an architecture diagram of the U-DNN-based analog circuit characterization system 800 according to some embodiments herein. The U-DNN-based analog circuit characterization system 800 for unified deep learning-based analog circuit characterization includes a data generation module 802, a neural network training module 804, a model validation module 806, a specification prediction module 808 and an adaptation module 810. The data generation module 802 is configured to interface with SPICE simulation environments 812 (e.g., SPICE Simulator or Silicon Measurement System) and generate PVT-aware training datasets. The neural network training module 804 implements a Bayesian optimization (BO) for hyperparameter tuning and maintaining a standardized five-layer architecture with 248×140×32×248×248 neuron configuration. The model validation module 806 enforces performance criteria of R² score and percentage errors. The specification prediction module 808 provides real-time circuit performance prediction for arbitrary PVT conditions. The adaptation module 810 generates control codes for self-adaptive circuit compensation. The U-DNN-based analog circuit characterization system 800 further includes an optimization module that combines primary PVT modeling with secondary component-level analysis for design improvement. The U-DNN-based analog circuit characterization system 800 further includes a second model generation module 814 that generates secondary models from silicon measurements of fabricated analog circuits.

In some embodiments, the neural network training module 804 is configured to achieve model convergence with minimal training data starting from 500 samples and adaptively increasing sample size based on accuracy requirements. In some embodiments, the datasets for the U-DNN and secondary models are built from silicon measurements of fabricated analog circuits instead of from SPICE simulation models.

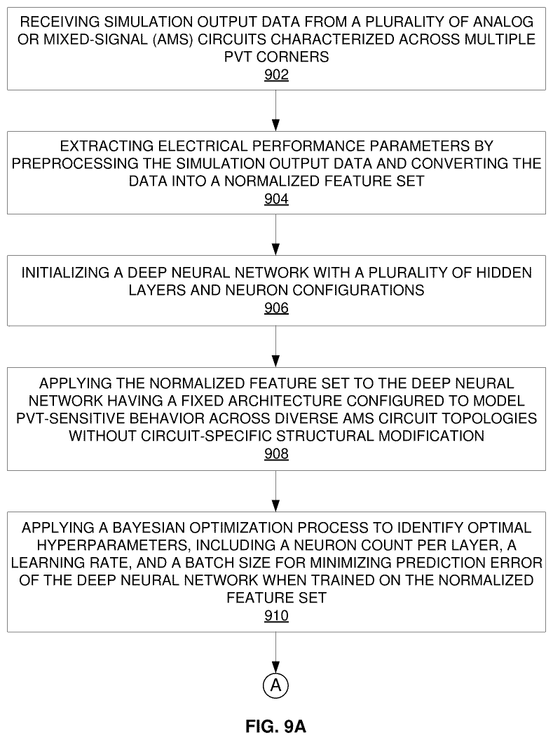

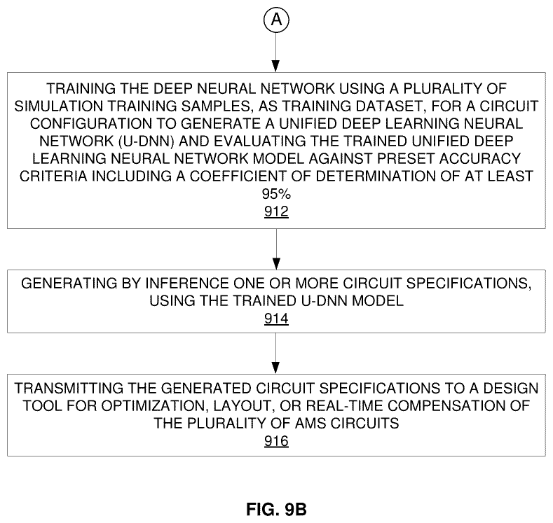

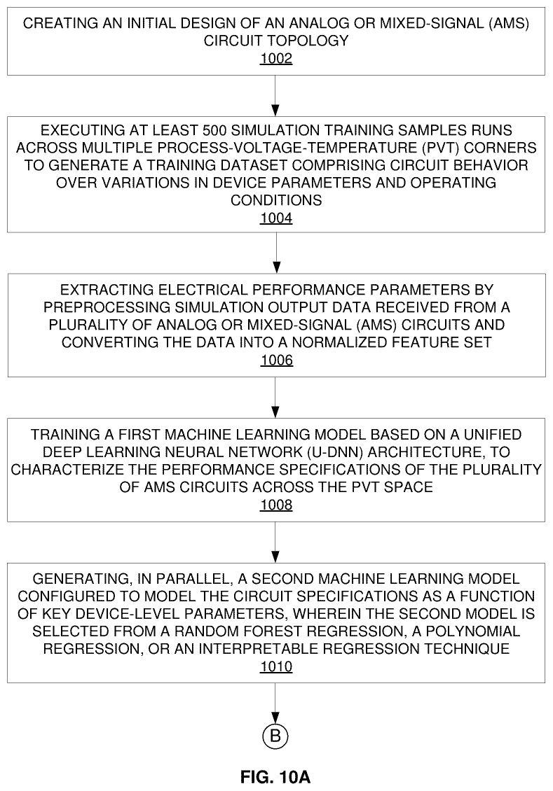

FIGS. 9A & 9B are flow diagrams that illustrate a computer-implemented method for creating a Unified Deep Learning Neural Network (U-DNN) to characterize circuit performance specifications for one or more analog and mixed-signal (AMS) circuits according to some embodiments herein. At step 902, simulation output data is received from one or more analog or mixed-signal (AMS) circuits characterized across multiple PVT corners. At step 904, electrical performance parameters are extracted by preprocessing the simulation output data and converting the data into a normalized feature set. At step 906, a deep neural network is initialized with one or more hidden layers and neuron configurations. At step 908, the normalized feature set is applied to the deep neural network having a fixed architecture configured to model PVT-sensitive behavior across diverse AMS circuit topologies without circuit-specific structural modification. At step 910, a Bayesian optimization process is applied to identify optimal hyperparameters, including a neuron count per layer, a learning rate, and a batch size for minimizing prediction error of the deep neural network when trained on the normalized feature set. At step 912, the deep neural network is trained using one or more simulation training samples, as training dataset, for a circuit configuration to generate a unified deep learning neural network (U-DNN) and evaluating the trained unified deep learning neural network model against preset accuracy criteria including a coefficient of determination of at least 95%. At step 914, one or more circuit specifications is generated by inference, using the trained U-DNN model. At step 916, the generated circuit specifications are transmitted to a design tool for optimization, layout, or real-time compensation of the one or more AMS circuits.

In some embodiments, the method includes (i) incrementally increasing the number of hidden layers and retraining the deep neural network if the preset accuracy criteria are not met, (ii) repeating the training process for additional AMS circuits using the same DNN architecture, and increasing the number of training samples per circuit if generalization goals are not met across diverse circuit topologies and (iii) upon satisfying both accuracy and generalization goals, storing the trained deep neural network as the unified U-DNN model for predicting circuit behavior across AMS designs.

In some embodiments, the training dataset includes at least 500 simulation training samples generated using SPICE simulation in Cadence Analog Design Environment, with PVT corner combinations selected to ensure MOSFETs operate within saturation or strong inversion regions. The number of simulation training samples per circuit beyond the at least 500 is dynamically adjusted based on real-time monitoring of prediction accuracy for unseen test samples.

In some embodiments, the U-DNN is trained using simulation datasets including one or more output features of the AMS circuit. The U-DNN is reused without architectural changes across different AMS circuit topologies, with circuit-specific accuracy achieved by additional fine-tuning of weights using circuit-specific training data.

In some embodiments, the PVT corners are selected from one or more process variations, voltage variations, and temperature variations. The neuron counts ranges at least from 32 to 256, learning rates ranges at least from 0.0001 and 0.1, and batch sizes ranges at least from 32 to 64, to minimize validation mean squared error.

In some embodiments, the method includes (i) validating the unified U-DNN model by verifying that it achieves a mean absolute percentage error (MaPE) below 1% or a pre-determined threshold and a standard deviation of prediction error (GE) below 1% or a pre-determined value across the PVT corner combinations, and (ii) determining circuit design parameters from transistor width (W), length (L), bias current (ID), load capacitance, and tail current source resistance, and adjust the circuit design parameters to meet the circuit specifications.

In some embodiments, the method includes (i) determining parameter delta values for components of the one or more AMS circuits and generating corresponding digital control codes to configure programmable analog blocks in real-time, (ii) automatically generating circuit specification reports and parametric plots for performance metrics over user-specified ranges of process, voltage, and temperature on a graphical interface, (iii) triggering automatic recalibration of circuit using parameter output of a secondary model, in response to predicted performance degradation under non-nominal process-voltage-temperature (PVT) conditions, and (iv) performing iterative U-DNN-based characterization and parameter compensation process across successive design revisions to converge on an AMS circuit that satisfies all specification constraints under worst-case PVT scenarios.

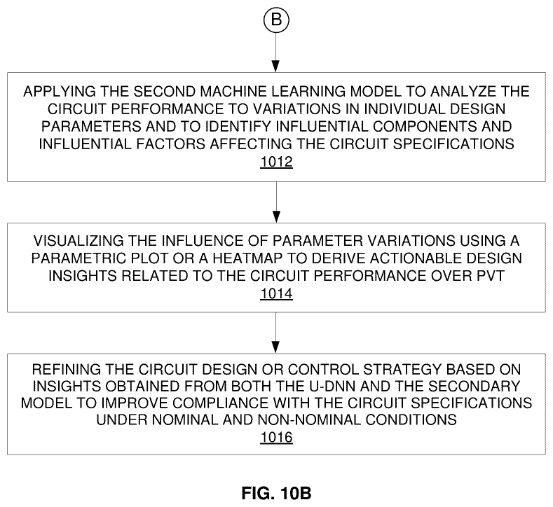

FIGS. 10A & 10B are flow diagrams that illustrate a computer-implemented method for characterizing performance specifications of a plurality of analog or mixed-signal (AMS) circuits using a Unified Deep Learning Neural Network (U-DNN) according to some embodiments herein. At step 1002, an initial design of an analog or mixed-signal (AMS) circuit topology is created. At step 1004, at least 500 simulation training samples are executed across multiple process-voltage-temperature (PVT) corners to generate a training dataset including circuit behavior over variations in device parameters and operating conditions. At step 1006, electrical performance parameters are extracted by preprocessing simulation output data received from one or more analog or mixed-signal (AMS) circuits and converting the data into a normalized feature set. At step 1008, a first machine learning model is trained based on a Unified Deep Learning Neural Network (U-DNN) architecture, to characterize the performance specifications of the one or more AMS circuits across the PVT space. At step 1010, a second machine learning model is generated, in parallel, that is configured to model the circuit specifications as a function of key device-level parameters. The second model is selected from a random forest regression, a polynomial regression, or an interpretable regression technique, At step 1012, the second machine learning model is applied to analyze the circuit performance to variations in individual design parameters and to identify influential components and influential factors affecting the circuit specifications. At step 1014, the influence of parameter variations are visualized using a parametric plot or a heatmap to derive actionable design insights related to the circuit performance over PVT. At step 1016, the circuit design is refined or control strategy based on insights obtained from both the U-DNN model and the secondary model to improve compliance with the circuit specifications under nominal and non-nominal conditions.

In some embodiments, the method further includes (i) re-centering the values of the influential component parameters of the AMS circuits based on insights obtained from the secondary machine learning model, (ii) generating an updated circuit design incorporating the re-centered parameters, (iii) re-executing a set of at least 500 simulations to retrain both the U-DNN model and the secondary model with updated circuit data, and (iv) performing a validation process by exercising a plurality of performance inquiries to verify that the updated circuit design satisfies the circuit specifications across the specified range of PVT corners.

In some embodiments, the method further includes (i) predicting, for each PVT condition, the deviation of one or more performance specifications of the AMS circuits from those obtained under nominal conditions, using the trained U-DNN model, (ii) determining, using the secondary machine learning model, updated values of the influential circuit component parameters required to compensate for the predicted deviations and restoring the specifications to nominal levels, and (iii) generating digital control codes to actuate adaptive elements of the circuit and apply the determined parameter adjustments in real-time.

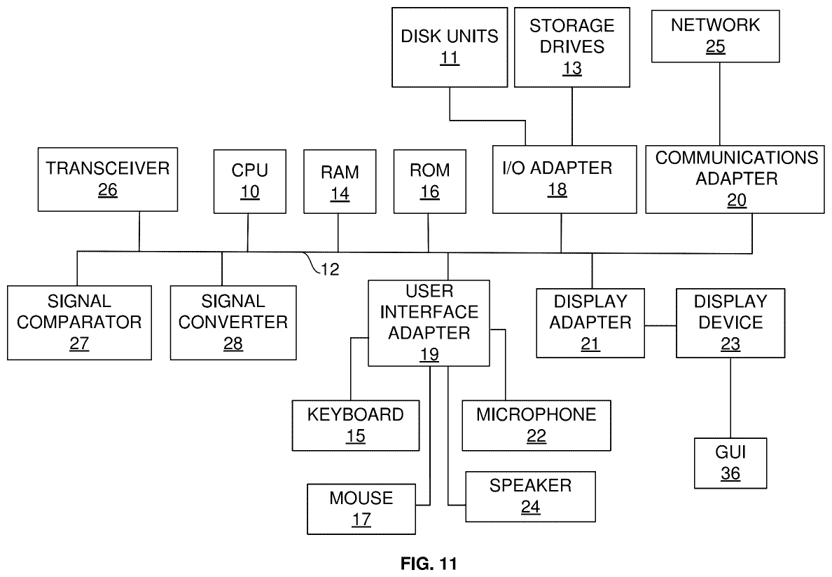

FIG. 11 is a representative hardware environment for practicing the embodiments herein. The various systems and corresponding components described herein and/or illustrated in the figures may be embodied as hardware-enabled modules and may be one or more overlapping or independent electronic circuits, devices, and discrete elements packaged onto a circuit board to provide data and signal processing functionality within a computer. An example might be a comparator, inverter, or flip-flop, which could include one or more transistors and other supporting devices and circuit elements. The systems that include electronic circuits process computer logic instructions capable of providing digital and/or analog signals for performing various functions as described herein. The various functions can further be embodied and physically saved as any of data structures, data paths, data objects, data object models, object files, and database components. For example, the data objects could include a digital packet of structured data. Example data structures may include any of an array, tuple, map, union, variant, set, graph, tree, node, or object, which may be stored and retrieved by computer memory and may be managed by processors, compilers, and other computer hardware components. The data paths can be part of a computer CPU or GPU that performs operations and calculations as instructed by the computer logic instructions. The data paths could include digital electronic circuits, multipliers, registers, and buses capable of performing data processing operations and arithmetic operations (e.g., Add, Subtract, etc.), bitwise logical operations (AND, OR, XOR, etc.), bit shift operations (e.g., arithmetic, logical, rotate, etc.), complex operations (e.g., using single clock calculations, sequential calculations, iterative calculations, etc.). The data objects may be physical locations in computer memory and can be a variable, a data structure, or a function. Some examples of the modules include relational databases (e.g., such as Oracle® relational databases), and the data objects can be a table or column, for example. Other examples include specialized objects, distributed objects, object-oriented programming objects, and semantic web objects. The data object models can be an application programming interface for creating HyperText Markup Language (HTML) and Extensible Markup Language (XML) electronic documents. The models can be any of a tree, graph, container, list, map, queue, set, stack, and variations thereof, according to some examples. The data object files can be created by compilers and assemblers and contain generated binary code and data for a source file. The database components can include any of tables, indexes, views, stored procedures, and triggers.

In an example, the embodiments herein can provide a computer program product configured to include a pre-configured set of instructions, which when performed, can result in actions as stated in conjunction with various figures herein. For example, the pre-configured set of instructions can be stored on a tangible non-transitory computer-readable medium. For example, the tangible non-transitory computer-readable medium can be configured to include the set of instructions, which when performed by a device, can cause the device to perform acts similar to the ones described here.

The embodiments herein may also include tangible and/or non-transitory computer-readable storage media for carrying or having computer-executable instructions or data structures stored thereon. Such non-transitory computer-readable storage media can be any available media that can be accessed by a general purpose or special purpose computer, including the functional design of any special purpose processor as discussed above. By way of example, and not limitation, such non-transitory computer-readable media can include RAM, ROM, EEPROM, CD-ROM or other optical disk storage, magnetic disk storage or other magnetic storage devices, or any other medium which can be used to carry or store desired program code means in the form of computer-executable instructions, data structures, or processor chip design. When information is transferred or provided over a network or another communications connection (either hardwired, wireless, or a combination thereof) to a computer, the computer properly views the connection as a computer-readable medium. Thus, any such connection is properly termed a computer-readable medium. Combinations of the above should also be included within the scope of the computer-readable media.

Computer-executable instructions include, for example, instructions and data which cause a special-purpose computer or special-purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Furthermore, the embodiments herein can take the form of a computer program product accessible from a computer-usable or computer-readable medium providing program code for use by or in connection with a computer or any instruction execution system. For the purposes of this description, a computer-usable or computer-readable medium can be any apparatus that can comprise, store, communicate, propagate, or transport the program for use by or in connection with the instruction execution system, apparatus, or device.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A computer-implemented method for creating a Unified Deep Learning Neural Network (U-DNN) to characterize circuit performance specifications for a plurality of analog and mixed-signal (AMS) circuits, comprising:
receiving simulation output data from a plurality of analog or mixed-signal (AMS) circuits characterized across multiple PVT corners;
extracting electrical performance parameters by preprocessing the simulation output data and converting the data into a normalized feature set;
initializing a deep neural network with a plurality of hidden layers and neuron configurations;
applying the normalized feature set to the deep neural network having a fixed architecture configured to model PVT-sensitive behavior across diverse AMS circuit topologies without circuit-specific structural modification;
applying a Bayesian optimization process to identify optimal hyperparameters, including a neuron count per layer, a learning rate, and a batch size for minimizing prediction error of the deep neural network when trained on the normalized feature set;
training the deep neural network using a plurality of simulation training samples, as training dataset, for a circuit configuration to generate a unified deep learning neural network (U-DNN) and evaluating the trained unified deep learning neural network model against preset accuracy criteria including a coefficient of determination of at least 95%;
generating by inference one or more circuit specifications, using the trained U-DNN model; and
transmitting the generated circuit specifications to a design tool for optimization, layout, or real-time compensation of the plurality of AMS circuits.

2. The computer-implemented method of claim 1, wherein the method comprises
incrementally increasing the number of hidden layers and retraining the deep neural network if the preset accuracy criteria are not met;
repeating the training process for additional AMS circuits using the same DNN architecture, and increasing the number of training samples per circuit if generalization goals are not met across diverse circuit topologies; and
upon satisfying both accuracy and generalization goals, storing the trained deep neural network as the unified U-DNN model for predicting circuit behavior across AMS designs.

3. The computer-implemented method of claim 1, wherein the training dataset comprises at least 500 simulation training samples generated using SPICE simulation in Cadence Analog Design Environment, with PVT corner combinations selected to ensure MOSFETs operate within saturation or strong inversion regions, wherein the number of simulation training samples per circuit beyond the at least 500 is dynamically adjusted based on real-time monitoring of prediction accuracy for unseen test samples.

4. The computer-implemented method of claim 1, wherein the U-DNN is trained using simulation datasets comprising one or more output features of the AMS circuit, wherein the U-DNN is reused without architectural changes across different AMS circuit topologies, with circuit-specific accuracy achieved by additional fine-tuning of weights using circuit-specific training data.

5. The computer-implemented method of claim 1, wherein the PVT corners are selected from one or more process variations, voltage variations, and temperature variations, wherein the neuron counts ranges at least from 32 to 256, learning rates ranges at least from 0.0001 and 0.1, and batch sizes ranges at least from 32 to 64, to minimize validation mean squared error.

6. The computer-implemented method of claim 1, wherein the method comprises
validating the unified U-DNN model by verifying that it achieves a mean absolute percentage error (MaPE) below 1% or a pre-determined threshold and a standard deviation of prediction error (σE) below 1% or a pre-determined value across the PVT corner combinations; and
determining circuit design parameters from transistor width (W), length (L), bias current (ID), load capacitance, and tail current source resistance, and adjust the circuit design parameters to meet the circuit specifications.

7. The computer-implemented method of claim 1, wherein the method comprises
determining parameter delta values for components of the plurality of AMS circuits and generating corresponding digital control codes to configure programmable analog blocks in real-time;
automatically generating circuit specification reports and parametric plots for performance metrics over user-specified ranges of process, voltage, and temperature on a graphical interface;
triggering automatic recalibration of circuit using parameter output of a secondary model, in response to predicted performance degradation under non-nominal process-voltage-temperature (PVT) conditions; and
performing iterative U-DNN-based characterization and parameter compensation process across successive design revisions to converge on an AMS circuit that satisfies all specification constraints under worst-case PVT scenarios.

8. A computer-implemented method for characterizing performance specifications of a plurality of analog or mixed-signal (AMS) circuits using a Unified Deep Learning Neural Network (U-DNN), comprising:
creating an initial design of an analog or mixed-signal (AMS) circuit topology;
executing at least 500 simulation training samples runs across multiple process-voltage-temperature (PVT) corners to generate a training dataset comprising circuit behavior over variations in device parameters and operating conditions;
extracting electrical performance parameters by preprocessing simulation output data received from a plurality of analog or mixed-signal (AMS) circuits and converting the data into a normalized feature set;
training a first machine learning model based on a Unified Deep Learning Neural Network (U-DNN) architecture, to characterize the performance specifications of the plurality of AMS circuits across the PVT space;
generating, in parallel, a second machine learning model configured to model the circuit specifications as a function of key device-level parameters, wherein the second model is selected from a random forest regression, a polynomial regression, or an interpretable regression technique;
applying the second machine learning model to analyze the circuit performance to variations in individual design parameters and to identify influential components and influential factors affecting the circuit specifications;
visualizing the influence of parameter variations using a parametric plot or a heatmap to derive actionable design insights related to the circuit performance over PVT; and
refining the circuit design or control strategy based on insights obtained from both the U-DNN and the secondary model to improve compliance with the circuit specifications under nominal and non-nominal conditions.

9. The computer-implemented method of claim 8, wherein the method further comprises
re-centering the values of the influential component parameters of the AMS circuits based on insights obtained from the secondary machine learning model;
generating an updated circuit design incorporating the re-centered parameters;
re-executing a set of at least 500 simulations to retrain both the U-DNN model and the secondary model with updated circuit data; and
performing a validation process by exercising a plurality of performance inquiries to verify that the updated circuit design satisfies the circuit specifications across the specified range of PVT corners.

10. The computer-implemented method of claim 8, wherein the method further comprises
predicting, for each PVT condition, the deviation of one or more performance specifications of the AMS circuits from those obtained under nominal conditions, using the trained U-DNN model;
determining, using the secondary machine learning model, updated values of the influential circuit component parameters required to compensate for the predicted deviations and restoring the specifications to nominal levels; and
generating digital control codes to actuate adaptive elements of the circuit and apply the determined parameter adjustments in real-time.

11. A system for creating a Unified Deep Learning Neural Network (U-DNN) used to characterize circuit performance specifications for a plurality of analog and mixed-signal (AMS) circuits, wherein the system comprises
a memory that stores a set of instructions; and
a processor that is configured to
receive simulation output data from a plurality of analog or mixed-signal (AMS) circuits characterized across multiple PVT corners;
extract electrical performance parameters by preprocessing the simulation output data and converting the data into a normalized feature set;
initialize a deep neural network with a plurality of hidden layers and neuron configurations;
apply the normalized feature set to the deep neural network having a fixed architecture configured to model PVT-sensitive behavior across diverse AMS circuit topologies without circuit-specific structural modification;
apply a Bayesian optimization process to identify optimal hyperparameters, including a neuron count per layer, a learning rate, and a batch size for minimizing prediction error of the deep neural network when trained on the normalized feature set;
train the deep neural network using a plurality of simulation training samples, as training dataset, for a circuit configuration to generate a unified deep learning neural network (U-DNN) and evaluating the trained unified deep learning neural network model against preset accuracy criteria including a coefficient of determination of at least 95%;
generate by inference one or more circuit specifications, using the trained U-DNN model; and
transmit the generated circuit specifications to a design tool for optimization, layout, or real-time compensation of the plurality of AMS circuits.

12. The system of claim 11, wherein the processor is configured to
incrementally increase the number of hidden layers and retraining the deep neural network if the preset accuracy criteria are not met;
repeat the training process for additional AMS circuits using the same DNN architecture, and increase the number of training samples per circuit if generalization goals are not met across diverse circuit topologies; and
upon satisfying both accuracy and generalization goals, store the trained deep neural network as the unified U-DNN model for predicting circuit behavior across AMS designs.

13. The system of claim 11, wherein the training dataset comprises at least 500 simulation training samples generated using SPICE simulation in Cadence Analog Design Environment, with PVT corner combinations selected to ensure MOSFETs operate within saturation or strong inversion regions, wherein the number of simulation training samples per circuit beyond the at least 500 is dynamically adjusted based on real-time monitoring of prediction accuracy for unseen test samples.

14. The system of claim 11, wherein the U-DNN is trained using simulation datasets comprising one or more output features of the AMS circuit, wherein the U-DNN is reused without architectural changes across different AMS circuit topologies, with circuit-specific accuracy achieved by additional fine-tuning of weights using circuit-specific training data.

15. The system of claim 11, wherein the PVT corners are selected from one or more process variations, voltage variations, and temperature variations, wherein the neuron counts ranges at least from 32 to 256, learning rates ranges at least from 0.0001 and 0.1, and batch sizes ranges at least from 32 to 64, to minimize validation mean squared error.

16. The system of claim 11, wherein the processor is configured to
validate the unified U-DNN model by verifying that it achieves a mean absolute percentage error (MaPE) below 1% or a pre-determined threshold and a standard deviation of prediction error (GE) below 1% or a pre-determined value across the PVT corner combinations; and
determine circuit design parameters from transistor width (W), length (L), bias current (ID), load capacitance, and tail current source resistance, and adjust the circuit design parameters to meet the circuit specifications.

17. The system of claim 11, wherein the processor is configured to
determine parameter delta values for components of the plurality of AMS circuits and generating corresponding digital control codes to configure programmable analog blocks in real-time;
automatically generate circuit specification reports and parametric plots for performance metrics over user-specified ranges of process, voltage, and temperature on a graphical interface;
trigger automatic recalibration of circuit using parameter output of a secondary model, in response to predicted performance degradation under non-nominal process-voltage-temperature (PVT) conditions; and
perform iterative U-DNN-based characterization and parameter compensation process across successive design revisions to converge on an AMS circuit that satisfies all specification constraints under worst-case PVT scenarios.

18. The system of claim 11, wherein the trained U-DNN and secondary model are deployed on an edge computing platform co-packaged with an adaptive analog circuit for real-time specification prediction and compensation against changing environmental conditions.

19. The system of claim 11, wherein the U-DNN comprises at least five hidden layers with neuron counts of 248, 140, 32, 248, and 248 respectively, and uses a rectified linear unit (ReLU) as an activation function.
